(19) United States
(12) Patent Application Publication
(10) Pub. No.: US 2006/0066231 A1
(43) Pub. Date: Mar. 30, 2006

(54) Electroluminescence element

(76) Inventors: Ryuji Nishikawa, Gifu-shi (JP); Nobuo Saito, Ichinomiya-shi (JP)

Correspondence Address: CANTOR COLBURN, LLP, 55 GRIFFIN ROAD SOUTH, BLOOMFIELD, CT, 06002, US

(21) Appl. No.: 11/238,734

(22) Filed: Sep. 29, 2005

(30) Foreign Application Priority Data
Sep. 30, 2004 (JP) 2004-289358
Sep. 30, 2004 (JP) 2004-289364

(51) Int. Cl. H01L 51/50; H05B 33/12

(52) U.S. Cl. 313/506; 313/504; 428/690; 428/917; 428/213

(57) ABSTRACT

An EL element includes, between an anode and a cathode, an emissive element layer including a plurality of emissive layers. The emissive element layer includes two or more organic layers containing a hole transporting compound, and one or more of the plurality of emissive layers contain the hole transporting compound. The concentration of the hole transporting compound in the organic layer which is formed closest to the electron injecting electrode among the organic layers containing the hole transporting compound is lower than the concentration of the hole transporting compound in the organic layer which is formed closest to the hole injecting electrode. When three or more organic layers contain a hole transporting compound, the concentration of the hole transporting compound contained in each organic layer can be set such that, as the organic layer is further away from the hole injecting electrode, the concentration is lower. With this setting, the supply amount and supply timing of holes and electrons can be optimized easily with regard to each of the plurality of emissive layers, so that uniform light emission can be generated in any one of the emissive layers.

### CROSS-REFERENCE TO RELATED APPLICATIONS

The entire disclosure of Japanese Patent Applications Nos. 2004-289358 and 2004-289364, including their specifications, claims, drawings, and abstracts, is incorporated herein by reference.

### BACKGROUND OF THE INVENTION

1. Field of the Invention

The present invention relates to a structure of an electroluminescence (hereinafter referred to as “EL”) element.

2. Description of Related Art

In recent years, self-emissive type EL elements have attracted attention as a display element for use in flat panel displays, light sources, and the like. In particular, organic EL elements capable of high brightness light emission in a variety of emission colors depending on the organic compound material employed are being actively studied and developed.

An organic EL element includes an emissive element layer including an emissive layer between a hole injecting electrode (anode) and an electron injecting electrode (cathode), and emits light when emissive molecules excited by a recombination energy generated at the time of recombination of holes injected from the anode and electrons injected from the cathodes in the emissive element layer return to their ground state.

As noted above, the organic EL element is capable of emitting light of various colors depending on an the organic emissive materials which are used. However, some colors, such as white, for example, cannot yet be obtained by a single organic emissive material. Therefore, such colors of light are achieved by combining light of a plurality of colors. For white light, it has been proposed that emissive layers of the complementary colors yellow and blue be layered within one element to thereby achieve white light emission by the additive of the yellow and blue lights obtained from the respective emissive layers. With this method, however, it is not always possible to configure the plurality of emissive layers to efficiently emit light, with the result that the color of the emitted light differs considerably from the reference white color.

Further, while organic EL elements are generally capable of high luminance light emission, a number of unsolved problems remain, including durability of the organic materials used for emissive material, such that the lives of such elements are therefore insufficient. When a plurality of emissive layers are layered to obtain light of an additive color, the emissive layer with the lowest light emission efficiency or the emissive layer with a large injection current will likely deteriorate faster than the other emissive layers. Consequently, the overall life of such an element depends on the life of the emissive layer with the shortest life span. Accordingly, in addition to the development of an organic emissive material with a longer life and a higher light emission efficiency for all the emission colors, there is also a demand for optimization of the element structure or the like.

### SUMMARY OF THE INVENTION

The present invention relates to a technology enabling highly efficient light emission of emissive layers and achieving a long life in an electroluminescence element including a plurality of emissive layers.

In accordance with an aspect of the present invention, there is provided an electroluminescence element comprising, between a hole injecting electrode and an electron injecting electrode, an emissive element layer including a plurality of emissive layers, wherein the emissive element layer includes two or more organic layers containing a hole transporting compound, one or more emissive layers of the plurality of emissive layers forming the organic layers containing a hole transporting compound, and the concentration of the hole transporting compound contained in an organic layer of the organic layers which is formed closest to the electron injecting electrode is lower than the concentration of the hole transporting compound contained in an organic layer of the organic layers which is formed closest to the hole injecting electrode.

In accordance with anther aspect of the present invention, the above electroluminescence element may include three or more organic layers containing a hole transporting compound, and the concentration of the hole transporting compound contained in the organic layers becomes lower as the organic layer is formed further away from the hole injecting electrode.

Further, the hole transporting compound may be an amine derivative compound, for example.

In accordance with another aspect of the present invention, in the above electroluminescence element, the plurality of emissive layers include a first emissive layer which is disposed closest to the hole injecting electrode and a second emissive layer which is disposed between the first emissive layer and the electron injecting electrode, at least a hole transport layer is provided between the first emissive layer and the hole injecting electrode, and when the concentration of the hole transporting compound contained in the hole transport layer is represented by Ch1, the concentration of the hole transporting compound contained in the first emissive layer is represented by Cem1, and the concentration of the hole transporting compound contained in the second emissive layer is represented by Cem2, then, the relationship Cem1−Cem2>Ch1−Cem1 is satisfied.

In accordance with a further aspect of the present invention, in the above electroluminescence element, of the plurality of emissive layers, at least a first emissive layer which is disposed closest to the hole injecting electrode and an emissive layer which is formed closest to the first emissive layer contain the same hole transporting compound.

As described above, when each of the plurality of organic layers contains a hole transporting compound, by setting the concentration of the hole transporting compound contained in these organic layers such that an organic layer disposed closer to the hole injecting electrode side contains the hole transporting compound at a higher concentration and an organic layer disposed further away from the hole injecting electrode side contains the hole transporting compound at a lower concentration, a necessary and sufficient amount of holes can be transported easily to each of the plurality of emissive layers formed between the hole injecting electrode and the electron injecting electrode.

In accordance with a further aspect of the present invention, in the above electroluminescence element, of the plurality of emissive layers, a first emissive layer is disposed closest to the hole injecting electrode and a second emissive layer is disposed between the first emissive layer and the electron injecting electrode, at least a hole transport layer is provided between the first emissive layer and the hole injecting electrode, at least an electron transport layer is provided between the second emissive layer and the electron injecting electrode, and the concentration of an electron transporting compound contained in the electron transport layer, the second emissive layer, and the first emissive layer is set such that as the layer is disposed further away from the electron transport layer, the concentration is lowered.

When the above relationship is satisfied, in addition to holes, electrons can also be injected uniformly to each emissive layer in an easy manner in an element in which a plurality of emissive layers are provided.

In accordance with another aspect of the present invention, in the above electroluminescence element, at least a hole transport layer and a hole injecting layer are provided between the hole injecting electrode and a first emissive layer, of the plurality of emissive layers, which is disposed closest to the hole injecting electrode, at least an electron transport layer is provided between the electron injecting electrode and a second emissive layer, of the plurality of emissive layers, which is disposed closest to the electron injecting electrode, and when a thickness and a hole mobility of the hole injecting layer are represented by Lhi and μhi, respectively, a thickness and a hole mobility of the hole transport layer are represented by Lht and μht, respectively, a thickness and a hole mobility of the first emissive layer are represented by Lem1 and μhem1, respectively, a thickness and an electron mobility of the second emissive layer are represented by Lem2 and μhem2, respectively, and a thickness and an electron mobility of the electron transport layer are represented by Let and μet, respectively, then the following relationship is satisfied:
(Lhi/μhi)+(Lht/μht)+(Lem1/μhem1)=α{(Lem2/μhem2)+(Let/μet)}
wherein α satisfies the relationship 0.5<α<2.5.

By setting the value of α within a range between 0.5 and 2.5, the task of causing electrons and holes to reach the first and second emissive layers, respectively, at equal timing is simplified. This can prevent an unbalanced state in which electrons and holes are recombined only in one of the emissive layers in a concentrated manner to cause light emission in one emissive layer while no light emission is generated in the other emissive layer.

According to the present invention, when a plurality of organic layers contain a common carrier transporting compound, the content (concentration) of the carrier transporting compound is set in steps such that the content is higher in an organic layer which is close to an electrode requiring the highest transporting ability and the content becomes lower as an organic layer is disposed further away from the electrode. With regard to at least two organic layers having different distances to the electrode, the concentration of the carrier transporting compound in the organic layer closer to the electrode is set higher than that in the other organic layer. Consequently, even in a case where one emissive layer is formed close to the electrode and the other emissive layer is formed further away from the electrode, it is easy to transport holes and electrons reliably to each emissive layer for recombination. Accordingly, the emission balance in each emissive layer can be increased, so that color formed by an additive desired colors can be obtained, and also such that an element with a high emission efficiency and a long life can be easily achieved.

In accordance with a further aspect of the present invention, there is provided an electroluminescence element comprising an emissive element layer including an organic compound between a hole injecting electrode and an electron injecting electrode, wherein the emissive element layer includes a plurality of emissive layers, and at least a hole transport layer is provided between the hole injecting electrode and a first emissive layer, of the plurality of emissive layers, which is disposed closest to the hole injecting electrode, and at least an electron transport layer is provided between the electron injecting electrode and a second emissive layer, of the plurality of emissive layers, which is disposed closest to the electron injecting electrode, and when the amount of time required for holes injected from the hole injecting electrode to pass through the hole transport layer and the first emissive layer to reach the second emissive layer is represented by Th and the amount of time required for electrons injected from the electron injecting electrode to pass through the electron transport layer and the second emissive layer to reach the first emissive layer is represented by Te, then the ratio of Th/Te satisfies the relationship 0.5<(Th/Te)<2.5.

In accordance with another aspect of the present invention, the above ratio Th/Te satisfies the relationship 1≦(Th/Te)<2.

As described above, when the ratio of time amounts required for the holes and the electrons to reach the respective emissive layers is set within the range between 0.5 and 2.5, it is easy to cause the electrons and the holes to reach the first emissive layer and the second emissive layer, respectively, at equal timing. It is therefore possible to prevent an unbalanced state in which the electrons and holes are recombined only in one of the emissive layers in a concentrated manner to cause light emission in one emissive layer while no light emission is generated in the other emissive layer. Consequently, it becomes easy to cause light emission in each of the plurality of emissive layers in a balanced manner. Further, by setting the ratio of the time amounts to 1 or greater and less than 2, more reliable and more efficient light emission can be achieved for any of a plurality of emissive layers in a layered structure.

In accordance with another aspect of the present invention, the first emissive layer has a hole transporting function and the second emissive layer has an electron transporting function.

When the above relationships are satisfied, holes and electrons can be injected in each emissive layer so as to achieve uniform light emission easily in an element in which a plurality of emissive layers are provided.

With the present invention, it is possible to improve the light emission balance among a plurality of layered emissive layers, so that a desired light created by combining desired colors can be achieved, and also so that an element with high efficiency and long life can be easily achieved.

### BRIEF DESCRIPTION OF THE DRAWINGS

A preferred embodiment of the present invention will be described in further detail based on the following drawings, wherein:

FIG. 1 is a schematic cross sectional view showing a structure of an EL element according to the preferred embodiment of the present invention;

FIG. 2 is a schematic cross sectional view showing a partial structure of a color display apparatus employing an EL element according to the embodiment of the present invention;

FIG. 3 is a view showing an emission spectrum of an EL element according to Example 1;

FIG. 4 is a view showing an emission spectrum of an EL element according to Comparison Example 1-2; and

FIG. 5 is a view showing an emission spectrum of an EL element according to Comparison Example 2-2.

### DETAILED DESCRIPTION OF PREFERRED EMBODIMENT

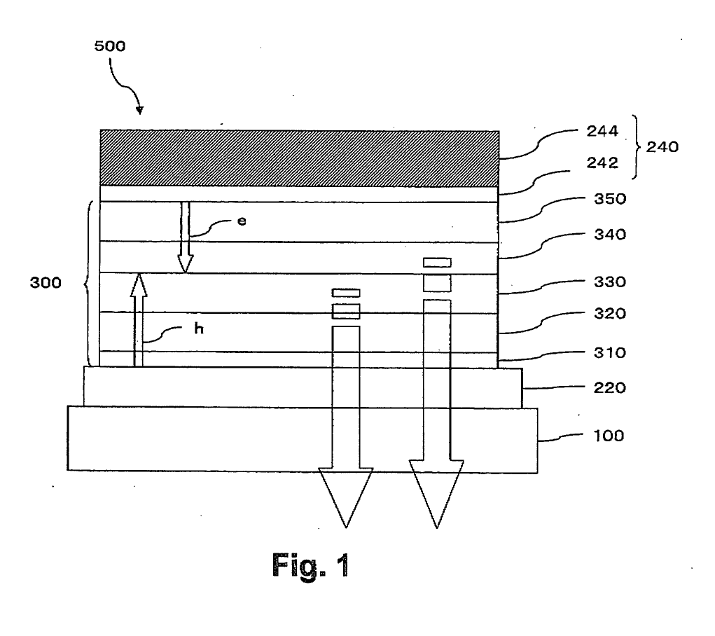

A preferred embodiment of the present invention will be described in detail with reference to the drawings. FIG. 1 schematically shows a cross sectional structure of an EL element 500 including a plurality of emissive layers between a first electrode and a second electrode according to the preferred embodiment of the present invention.

One of the first and second electrodes is a hole injecting electrode (anode) 220 and the other is an electron injecting electrode (cathode) 240. In the example shown in FIG. 1, the anode 220 is formed toward a substrate, and the cathode 240 is formed such that the cathode 240 is opposed to the anode 220 with an emissive element layer 300 including an organic compound interposed between these electrodes.

The emissive element layer 300 includes a plurality of organic layers containing a hole transporting compound. Further, the emissive element layer 300 includes a plurality of emissive layers. The emissive element layer 300 includes at least a hole transport layer 320 between the anode 220 and a first emissive layer 330, of the plurality of emissive layers, which is disposed closest to the anode 220 and includes at least an electron transport layer 350 between the cathode 240 and a second emissive layer 340, of the plurality of emissive layers, which is disposed closest to the cathode 240. In the example shown in FIG. 1, the emissive element layer 300 is configured such that, from the anode 220 side, a hole injecting layer 310, the hole transport layer 320, the first emissive layer 330, the second emissive layer 340, and the electron transport layer 350 are sequentially layered, although the structure of the emissive element layer 300 may vary depending on an organic material which is employed, or the like.

Further, in the present embodiment, in order to achieve white light emission by additive color, an orange emissive layer and a blue emissive layer are used as the first emissive layer 330 and the second emissive layer 340, respectively. While the structure including these color layers is not limited to the illustrated structure in which the orange emissive layer and the blue emissive layer are layered in this order from the hole transport layer side, it is preferable to dispose the emissive layer having a high hole transporting function towards the anode 220 for use as the first emissive layer 300 and dispose the emissive layer having a high electron transporting function towards the cathode 240 for use as the second emissive layer 340.

The number of emissive layers is not limited to two and three or more layers may be employed. When three or more emissive layers are provided, between the first emissive layer 330 which is closest to the anode 220 (i.e. furthest from the cathode 240) and the second emissive layer 340 which is closest to the cathode 240 (i.e. furthest from the anode 220) among the plurality of emissive layers, a third, a fourth, . . . the n-th emissive layers are provided. Further, a function layer other than an emissive layer may be formed between the emissive layers provided between the first and second emissive layers or between the first and second emissive layers.

The structures of each of the hole transport layer 320 and the electron transport layer 350 is not limited to a single layer structure, and either layer may adopt a multilayer structure, Further, the hole transport layer 320 and the electron transport layer 350 may be eliminated. When the hole transport layer 320 is eliminated, the first emissive layer 330 may also function as the hole transport layer, and when the electron transport layer 350 is eliminated, the second emissive layer 340 may also function as the electron transport layer. Also, the structure of the hole injecting layer 310 is not limited to a single layer structure and may adopt a multilayer structure. The hole injecting layer 310 may be eliminated when a hole injection barrier from the anode 220 to the hole transport layer 320 is relatively small.

For the anode 220, a conductive metal oxide material is used, for example. More specifically, a transparent conductive material such as ITO (Indium Tin Oxide) or IZO (Indium Zinc Oxide) may be used. The cathode 240 is formed by a layered structure including a metal layer 244 made primarily of a metal material having a superior work function and an electron injecting layer 242, which is provided so as to decrease an electron injection barrier to the electron transport layer 350. For the metal layer 244, Al, Ag, an MgAl alloy, an LiAl alloy, an LiAg alloy, or the like may be employed. The electron injecting layer 242, which may be eliminated when an electron injection barrier from the cathode 240 to the electron transport layer 350 is small, may be formed by lithium fluoride (LiF), lithium (Li), and the like.

The hole injecting layer 310 may be formed by CuPc (copper phthalocyanine complex), CFx (where x is an arbitrary number), and the like.

The hole transport layer 320 contains a hole transporting compound at a very high concentration (for example, 100 percent by mass). As an example of the hole transporting compound, an amine derivative compound exhibiting a high hole mobility, and more particularly, an aromatic amine derivative compound may be used. The aromatic amine derivative compound may mainly include dimer or higher multimer of triphenylamine or a derivative thereof. More specifically, TPD (N,N′-bis(3-methylphenyl)-N,N′-diphenyl-1,1′-biphenyl-4,4-diamine), NPB (N,N′-bis(1-naphthyl)-N,N-diphenyl-(1,1′-biphenyl-4,4′-diamine), 1-TNATA (4,4′4″-tris[1-naphthyl(phenyl)amino]-triphenylamine), or the like may be used.

The electron transport layer 350 contains an electron transporting compound at a very high concentration (for example, 100 percent by mass). As an example of the electron transporting compound, an organic metal complex compound exhibiting a high electron mobility, such as aluminum quinolinol complex (Alq), or a nitrogen-containing heterocyclic compound such as phenanthroline may be used.

In the example shown in FIG. 1, the first emissive layer 330, which is the closest to the anode among the plurality of emissive layers, is formed contiguously on the hole transport layer 320 having a single layer structure and contains a hole transporting compound at a relatively high concentration. More specifically, the first emissive layer 330 is formed by doping a dopant material, which is an emissive material of orange color, into a host material, which is a hole transporting compound, at a concentration of 10 percent by mass or less, Namely, the first emissive layer 330 contains the hole transporting compound at a concentration of 100 to 80 percent by mass or a greater concentration (approximately 90 percent by mass, for example). An aromatic amine derivative compound which is employed for the hole transport layer 320 may be used as the hole transporting material. The orange color emissive material (a dopant material) is not particularly limited, and may, for example, be rubrene(5,6,11,12-tetraphenyl naphthacene), DBzR (5,12-bis(4-(6-methylbenzohiazole-2-yl)phenyl)-6,11-diphenyl naphthacene), or the like. Here, when the dopant material exhibits not only the light emitting function but also a high hole transporting ability, the concentration of the hole transporting compound in the first emissive layer 330 may be approximately 100 percent by mass.

In the example shown in FIG. 1, the second emissive layer 340, of the plurality of emissive layers, which is the closest to the cathode 240 is formed immediately above the first emissive layer 330 and is contiguous to both the first emissive layer 330 and the electron transport layer 350. The second emissive layer 340 contains at least an electron transporting compound at a high concentration. In the present embodiment, with both a hole transporting compound and an electron transporting compound being used as host materials and a blue emissive material being used as a dopant material, the second emissive layer 340 is formed by doping the dopant material into the host material at a concentration of 10 percent by mass or less.

In the second emissive layer 340, an aromatic amine derivative compound may be used as the hole transporting host material as in the case of the first emissive layer, and an organic metal complex compound which is employed in the electron transport layer 350 and also a polycyclic aromatic compound may be employed as the electron transporting host material. As for the metal complex compound, aluminum quinolinol complex or its derivative, for example, may be used, as described above. The polycyclic aromatic compound may include an anthracene compound, for example.

An example of the anthracene compound can include ADN (9,10-di(2-naphthyl)anthracene), and so on. The above-described polycyclic aromatic compound, which exhibits a hole transporting property as well as an electron transporting property, may also be used as an assist dopant for the first emissive layer 330. In this case, DPN (5,12-diphenylnaphthacene), for example, may be employed for the assist dopant. While the blue emissive material (a dopant material) is not particularly limited, a perylene compound and a pyrene compound, for example, may be used.

The concentration of the hole transporting compound in the second emissive layer 340 can be set to 0 to 50 percent by mass, while the concentration of the electron transporting compound in the second emissive layer 340 can be set to 50 to 100 percent by mass. Here, when a compound having both a light emitting function and an electron transporting function, such as Alq₃, is used for the second emissive layer 340, a single electron transporting emissive compound may be used at a concentration of 100 percent by mass.

As described above, according to the present embodiment, when the organic element layer includes two emissive layers 330 and 340 and a hole transporting compound is contained at least in the hole transport layer 320 and the first emissive layer 330, the concentration of the hole transporting compound contained in the first emissive layer 330 is made equal to or lower than the concentration of the hole transporting compound contained in the hole transport layer 320. When the emissive material employed for the first emissive layer 330 exhibits both the light emitting function and the hole transporting function, the concentration of the hole transporting compound contained in the first emissive layer 330 can be approximately 100 percent by mass. While a hole transporting compound may also be partially employed in the second emissive layer 340, even in such a case, the concentration of the hole transporting compound contained in the second emissive layer 340 is lower than that in the first emissive layer 330. As such, it is preferable to set the concentration of the hole transporting compound contained in a plurality of organic layers such that a layer formed further away from the anode 220 contains the hole transporting compound at a lower concentration. Further, when a plurality of organic layers contain an electron transporting compound, the concentration of the electron transporting compound contained in the plurality of organic layers can be set such that an organic layer formed closer to the cathode 240 contains the electron transporting compound at a higher concentration.

The organic EL element 500 has the layered structure described above, in which each layer is formed sequentially, starting from the anode 220, on a transparent insulating substrate 100 such as a glass or a plastic film. The anode 220 can be formed by a sputtering method, for example, and the emissive element layer 300 and the cathode 240 can be formed successively by a vacuum deposition method, for example. When the organic EL element 500 is applied to a so-called active matrix type display apparatus in which the organic EL element 500 is used as a display element (an emissive element) in each pixel of the display apparatus and also a transistor is provided for each pixel for storing and controlling the display content for each pixel, layers constituting a each pixel circuit such as a transistor are provided between the substrate 100 and the anode 220.

With the above structure, holes injected from the anode 220 are further injected into the hole injecting layer 310, pass through the hole transport layer 320 containing a hole transporting compound at a high concentration, and reach the first emissive layer 330. Further, because the first emissive layer 330 contains a high concentration of the hole transporting compound as a host material and therefore has a hole transporting property, the holes pass through the first emissive layer 330 and further reach the second emissive layer 340.

On the other hand, electrons injected from the cathode 240 (injected via the electron injecting layer 242 from the metal layer 244) pass through the electron transport layer 350 containing a high concentration of an electron transporting compound, and reach the second emissive layer 340. Further, as the second emissive layer 340, which contains a high concentration of the electron transporting compound, also has an electron transporting property as described above, the electrons pass through the second emissive layer 340 and further reach the first emissive layer 330.

Consequently, in the first emissive layer 330, the holes injected from the anode 220 and the electrons which have reached from the cathode 240 via the second emissive layer 340 are recombined to generate a recombination energy, which excites emissive molecules which are dopant, and orange light is emitted when the emissive molecules return back to the ground state. In the second emissive layer 340, on the other hand, the holes which have reached from the anode 220 via the first emissive layer 330 and the electrons injected from the cathode 240 are recombined, and light emission of a blue color can be obtained when excited emissive molecules which are dopant return back to the ground state. In the example shown in FIG. 1, both the blue light obtained in the second emissive layer 340 and the orange light obtained in the first emissive layer 330 externally exit from the side of the transparent anode 220 through the substrate 100 formed by a transparent insulating material such as glass. Consequently, white light is externally viewed due to an additive color of the blue light and the orange light.

As described above, in the present embodiment, when a plurality of organic layers containing a hole transporting compound are layered as the emissive element layer 300, the concentration of the hole transporting compound is set such that the closer to the anode 220 the organic layer is disposed, the higher the concentration of the hole transporting compound. In particular, when the concentration of the hole transporting compound in the hole transport layer 320 is represented by Ch1, the concentration of the hole transporting compound in the first emissive layer 330 is represented by Cem1, and the concentration of the hole transporting compound in the second emissive layer 340 is represented by Cem2, it is preferable that the following relationship is satisfied:
Cem1−Cem2>Ch1−Cem1

The hole transporting property of the second emissive layer 340 can be decreased to a level lower than that of the first emissive layer 330 by increasing the difference in concentrations of the hole transporting compound between the first emissive layer 330 and the second emissive layer 340, and particularly by decreasing the concentration Cem2. If the holes pass through the second emissive layer 340 and reach the cathode 240, these holes causes a reactive current, thereby making no contribution to light emission. Further, even if these holes are recombined with electrons between the second emissive layer 340 and the cathode 240, it is possible that no light will be emitted because emissive molecules normally exist only in emissive layers. Also, when a material which exhibits a light emitting function as well as an electron transporting property is used for the electron transport layer 350, undesirable light emission occurs in the electron transport layer 350, which results in decrease of color purity. It is therefore desirable to satisfy the above-described relationship of the concentration.

When three or more emissive layers are provided, further emissive layers are formed between the first emissive layer 330 and the second emissive layer 340, as described above. In this case, in the first emissive layer 330 for which a high level hole transporting ability is required, the concentration of the hole transporting compound is preferably high, such as approximately 100 to 90 percent by mass, for example. In the second emissive layer 340, on the other hand, because a high level electron transporting ability is required, the concentration of the electron transporting compound is set preferably high, such as approximately 100 to 50 percent by mass, for example. Among the emissive layers formed between the first emissive layer 330 and the second emissive layer 340, the emissive layer which is the closest to the first emissive layer 330 must transport holes toward the second emissive layer 340 side and therefore contains a hole transporting compound. The concentration of the hole transporting compound contained in this intermediate emissive layer is set lower than that of the first emissive layer 330 and higher than that of the second emissive layer 340. Here, the same hole transporting compound can be used for both the emissive layer which is the closest to the first emissive layer 330 (which is the second emissive layer 340 when two emissive layers are provided) and the first emissive layer 330. The use of the same material facilitates efficient formation of the emissive layers by means of a common deposition source when each layer of the emissive layer element 300 is formed by a vacuum deposition method, for example.

The characteristics of the electroluminescence element according to the present embodiment which is formed based on the concentration relationship described above will be described. First, the amount of time per unit distance required for holes injected from the anode 220 to pass through the hole injecting layer 310, the hole transport layer 320, and the first emissive layer 330 and reach the second emissive layer 340 is represented as Th. Further, the amount of time per unit distance required for electrons injected from the cathode 240 to pass through the electron transport layer 350 and the second emissive layer 340 and reach the first emissive layer 330 is represented as Te. In this case, in the organic EL element 500 according to the present embodiment in which the concentrations are optimized as described above, the ratio (Th/Te) satisfies the relationship of 0.5<(Th/Te)<2.5, more preferably 1≦(Th/Te)<2, and most preferably 1.3<(Th/Te)<1.7.

When the ratio of the time amounts required for the holes and the electrons to reach the first and second emissive layers satisfies the above relationships, the timing at which the holes and the electrons reach the first emissive layer 330 can be approximated to the timing at which the holes and the electrons reach the second emissive layer 340.

When a difference between Th and Te is too large, such as if Th is 2.5 times as great as Te or greater, while the electrons and holes do reach the first emissive layer 330 which is the closest to the anode at substantially the same timing to cause light emission therein, by the time the holes reach the second emissive layer 340 which is the closest to the cathode 240, the electrons have already passed through the electron transporting second emissive layer 340. In such a case, in the second emissive layer 340, the probability of recombination of electrons and holes is low, which results in insufficient light emission. If the timing of electrons and holes reaching the first and second emissive layers as described above is reversed, light emission can be achieved only in the second emissive layer and the first emissive layer does not emit light. Thus, even if a plurality of emissive layers are provided, only a portion of the emissive layers emit light and a desired additive color light (white light in this example) which is well balanced cannot be obtained, unless the ratio of the required time amounts is optimized. However, when the ratio of the required time amounts satisfies the above-described relationships and is therefore in the range of 1.3 to 1.7, for example, the reaching timings with regard to the holes and the electrons can be matched, thereby allowing each of the plurality of emissive layers to emit light in a balanced manner. Here, one of the reasons why the desirable ratio of the required time amounts Th/Te is 1 or greater is as follows. Specifically, with such a ratio, the timing at which holes reach the second emissive layer 340 can be controlled as described above, and in addition, by maximizing the thickness of the emissive layer in the emissive element layer 300 which is disposed toward the anode side and which is likely to be uneven under influence of the lower layers, disconnection of the emissive element layer 300 can be prevented and the ability to cover the steps of the layers can be increased.

In the present embodiment, the above-described required time amounts Th and Te can be adjusted in consideration of the carrier mobility (cm²/Vs) of the carrier transporting material and the concentration (and more preferably, the thickness as well) of each layer of the emissive element layer 300. Here, it is generally known that the carrier transporting materials (the hole transporting material and the electron transporting material) employed in the emissive element layer 300 exhibit the carrier mobility (i.e. the hole mobility and the electron mobility) in the range of 10⁻³ to 10⁻⁶, and that the mobility in such a range can be generally achieved at a fixed high concentration of the carrier transporting material. Further, the greater the concentration, the greater the mobility. Accordingly, the above-described characteristics can be achieved by optimizing the concentration of the carrier transporting material contained in each layer and adjusting the thickness of each layer.

The carrier mobility, the thickness, and the concentration of each layer will be described.

First, the hole mobility of an aromatic amine derivative compound employed for the material of the hole transport layer 320 and for the host material of the first emissive layer 330 is 10⁻³ cm²/Vs to 10⁻⁴ cm²/Vs (at the concentration of approximately 100 percent by mass).

The electron mobility of an organic metal complex compound employed for the material of the electron transport layer 350 and for the host material of the second emissive layer 340 is 10⁻⁴ cm²/Vs to 10⁻⁶ cm²/Vs (at the concentration of approximately 100 percent by mass). When a polycyclic aromatic compound, which has both a hole transporting property and an electron transporting property, is used as the electron transporting host material of the second emissive layer 340, the electron mobility is 10⁻³ cm²/Vs to 10⁻⁵ cm²/Vs and the hole mobility is also 10⁻³ cm²/Vs to 10⁻⁵ cm²/Vs.

The above-described hole mobility and electron mobility can be obtained by measurement using the Time-of-Flight (TOF) method. Specifically, in the TOF method, a material film which is a measurement subject (in the present embodiment, an organic compound material film of each layer) is formed at a concentration of approximately 100 percent by mass and sandwiched between opposing electrodes, and carriers are generated at the interface between the material film and one of the electrodes, whereby the time required for the carriers to reach the other opposed electrode is measured.

As described above, the hole mobility of an organic compound which is known to have a hole transporting property is in the range of 10⁻³ cm²/Vs to 10⁻⁵ cm²/Vs when the film is formed at a concentration of approximately 100 percent by mass, and the electron mobility of an organic compound which is known to have an electron transporting property is in the range of 10⁻³ cm²/Vs to 10⁻⁶ cm²/Vs when the film is formed at a concentration of approximately 100 percent by mass.

Then, the thickness of each layer will be described. The thickness of the hole injecting layer 310 is 0.5 nm to 5.0 nm (in the case of CFx), or 10 nm to 20 nm (in the case of CuPc). The thickness of the hole transport layer 320 is 30 nm to 300 nm, the thickness of the first emissive layer 330 is 10 nm to 150 nm, and the thickness of the second emissive layer 340 is 20 nm to 50 nm, and the thickness of the electron transport layer 350 is 10 nm to 30 nm.

The relationship between the carrier mobility and the thickness of each layer of the emissive element layer 300 can be represented by the following expression (1):
(Lhi/μhi)+(Lht/μht)+(Lem1/μhem1)=α{(Lem2/μhem2)+(Let/μet)} (1)
wherein α satisfies the relationship of 0.5<α<2.5. In the above expression (1), Lhi represents the thickness of the hole injecting layer 310, λhi represents the hole mobility of the hole injecting layer 310, Lht represents the thickness of the hole transport layer 320, μht represents the hole mobility of the hole transport layer 320, Lem1 represents the thickness of the first emissive layer 330, μhem1 represents the hole mobility of the first emissive layer 330, Lem2 represents the thickness of the second emissive layer 340, μhem2 represents the electron mobility of the second emissive layer 340, Let represents the thickness of the electron transport layer 350, and μet represents the electron mobility of the electron transport layer 340. More preferably, a satisfies the relationship of 1≦α<2, and most preferably in the range of 1.3<α<1.7. By setting the value of α to greater than 0.5 and smaller than 2.5, it is possible to allow both the first and second emissive layers 330 and 340 to emit light in a balanced manner and to obtain an element structure free from disconnection, which can easily achieve a longer life.

Next, six types of organic EL elements 500 in which the concentration of a carrier transporting compound is different for each element and the thickness of each layer is the same for all the elements will be described. In each of the EL elements 500 according to Comparative Examples 1-1 and 1-2, the concentrations of a hole transporting material and an electron transport material included in the first emissive layer (EML1) differ from the concentrations of a hole transporting material and an electron transport material included in the first emissive layer (EML1) of the EL element 500 according to Example 1. Further, in each of the EL elements 500 according to Comparative Examples 2-1 and 2-2, the concentrations of a hole transporting material and an electron transport material included in the second emissive layer (EML2) differ from the concentrations of a hole transporting material and an electron transport material included in the second emissive layer (ENL2) of the EL element 500 according to Example 2.

In the EL element 500, CuPu was used for the hole injecting layer (HIL) 310 (at a thickness of 10 nm), and the hole transport layer (HTL) 320 was formed at a thickness of 100 nm, using NPB, which is one type of aromatic amine compound. The first emissive layer (EML1) 330 was formed at a total thickness of 30.9 nm, in which NPB having a hole transporting property was used as a host material, DBzR was used as a dopant, and DPN (5,12-diphenylnaphtacene) was used as an assist dopant (an orange emissive layer). The second emissive layer (EML2) 340 was formed at a thickness of 41.0 nm, in which a polycyclic aromatic compound, more particularly ADN (9,10-di(2-naphthyl)anthracene) which is an anthracene compound, was used as a host material, a peryrene compound (BD:peryrene) was used as a dopant, and NPB was added as a hole transporting compound (a blue emissive layer). Further, the electron transport layer (ETL) 350 was formed at a thickness of 10 nm, using Alq₃ (tris(8-hycroxyquinolinate)aluminum (III)). Here, the above-described DPN, which is an assist dopant, exhibits both the hole transporting property and the electron transporting property, and the concentration of this DPN was evaluated as the concentration of the electron transporting compound in the first emissive layer.

TABLE 1

| | HTL | | | | | | | ETL | |
|---|---|---|---|---|---|---|---|---|---|
| | (100 nm) | EML1 (30.9 nm) | | | 52 EML2 (41.0 nm) | | | (10 nm) | Light |
| | NPB | NPB | DPN | DBzR | ADN | NPB | BD | Alq | Emission |
| | Con- | Con- | Con- | Con- | Con- | Con- | Con- | Con- | Efficiency |
| | centration | centration | centration | centration | centration | centration | centration | centration | (cd/A) |
| Example 1 | 100% | 93.9% | 3.2% | 2.9% | 90.2% | 7.3% | 2.4% | 100% | 14 |
| | (100 nm) | (29.0 nm) | (1.0 nm) | (0.9 nm) | (37.0 nm) | (3.0 nm) | (1.0 nm) | (10 nm) | |
| Comparative | 100% | 87.4% | 9.7% | 2.9% | 90.2% | 7.3% | 2.4% | 100% | 12 |
| Example | (100 nm) | (27.0 nm) | (3.0 nm) | (0.9 nm) | (37.0 nm) | (3.0 nm) | (1.0 nm) | (10 nm) | |
| 1-1 | | | | | | | | | |
| Comparative | 100% | 77.7% | 19.4% | 2.9% | 90.2% | 7.3% | 2.4% | 100% | 10 |
| Example | (100 nm) | (24.0 nm) | (6.0 nm) | (0.9 nm) | (37.0 nm) | (3.0 nm) | (1.0 nm) | (10 nm) | |
| 1-2 | | | | | | | | | |
| Example 2 = Example 1 | 100% | 93.9% | 3.2% | 2.9% | 90.2% | 7.3% | 2.4% | 100% | 14 |
| | (100 nm) | (29.0 nm) | (1.0 nm) | (0.9 nm) | (37.0 nm) | (3.0 nm) | (1.0 nm) | (10 nm) | |
| Comparative | 100% | 93.9% | 3.2% | 2.9% | 82.9% | 14.6% | 2.4% | 100% | 11 |
| Example | (100 nm) | (29.0 nm) | (1.0 nm) | (0.9 nm) | (34.0 nm) | (6.0 nm) | (1.0 m) | (10 nm) | |
| 2-1 | | | | | | | | | |
| Comparative | 100% | 93.9% | 3.2% | 2.9% | 82.9% | 19.5% | 2.4% | 100% | 7 |
| Example | (100 nm) | (29.0 nm) | (1.0 nm) | (0.9 nm) | (34.0 nm) | (8.0 nm) | (1.0 nm) | (10 nm) | |
| 2-2 | | | | | | | | | |

The above Table 1 shows the concentration (weight %) of a carrier transporting compound, a converted film thickness (nm) of each layer, and light emission efficiency (cd/A) of each element with regard to the EL element in each of Example 1, Comparative Example 1-1, Comparative Example 1-2, Example 2, Comparative Example 2-1, and Comparative Example 2-2.

In the EL element 500 of Example 1, the concentrations of a hole transporting compound (NPB) in HTL/EML1/EML2/ETL were 100%/93.9%/7.3%/0%, respectively.

In comparison, in the EL elements of Comparative Examples 1-1 and 1-2, while the NPB concentrations of the HTL and EML2 were 100% and 7.3%, respectively, which are the same as those in Example 1, the NPB concentrations of the EML1 were 87.4% and 77.7% in Comparative Examples 1-1 and 1-2, respectively, which were lower than that in Example 1.

Further, in the EL element 500 of Example 1, the concentrations of the electron transporting compound in HTL/EML1(DPN concentration)/EML2(ADN concentration)/ELT (Alq concentration) were 0%/3.2%/90.2%/100%, respectively. In comparison, in the EL elements of Comparative Examples 1-1 and 1-2, the concentrations of the electron transporting material in the HTL and the EML2 were the same as those in Example 1, and the concentrations of the electron transporting compound (DPN) in the EML1 which was disposed between the HTL and the EML2 were 9.7% and 19.4% in Comparative Examples 1-1 and 1-2, respectively, which were higher than that in Example 1. In these Example 1, Comparative Example 1-1, and comparative Example 1-2, the light emission efficiencies were 14, 12, and 10, respectively, which shows that as the concentration of a hole transporting compound contained in the first emissive layer (EML1) decreased (i.e. as the concentration of an electron transporting compound increases), the efficiency was lowered.

Here, an α value of the EL element in each of the above examples can be obtained from a converted thickness value of a layer of each of a plurality of materials, which has a specific mobility, forming the first and second emissive layers, when the layer is formed by layering each material at a concentration of 100%. Such an α values is 1 for the EL element in Example 1 and is 2.5 for the EL element in Comparative Example 1-2.

In Table 1, these reference values of the converted thickness are described with the concentrations Specifically, in Example 1, these reference values are, sequentially from the hole transport layer, NPB (100 nm)/NPB (2.9 nm)+DPN (1.0 nm)+DBzR (0.9 nm)/ADN (37.0 nm)+NPB (3.0 nm)+BD (1.0 nm)/Alq (10 nm).

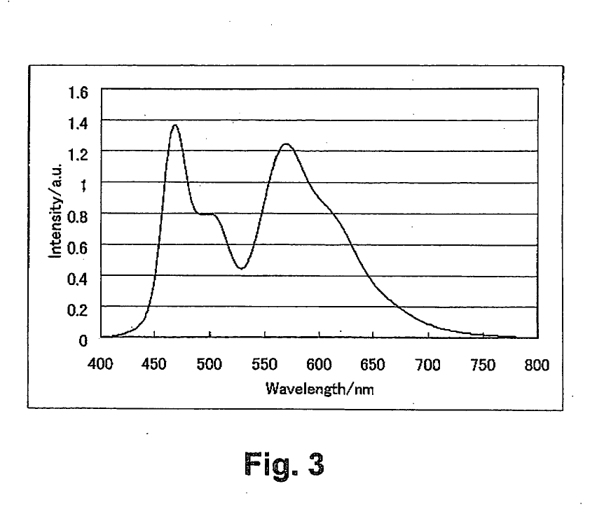

FIG. 3 shows the emission spectrum intensity of the EL element 500 (α=1) of Example 1. In this EL element 500, both the first emissive layer 330 and the second emissive layer 340 emitted light in a balanced manner and desirable white light could be obtained, with an excellent light emission efficiency of 14 cd/A (i.e. the power efficiency is 6.1 lm/W) as described above.

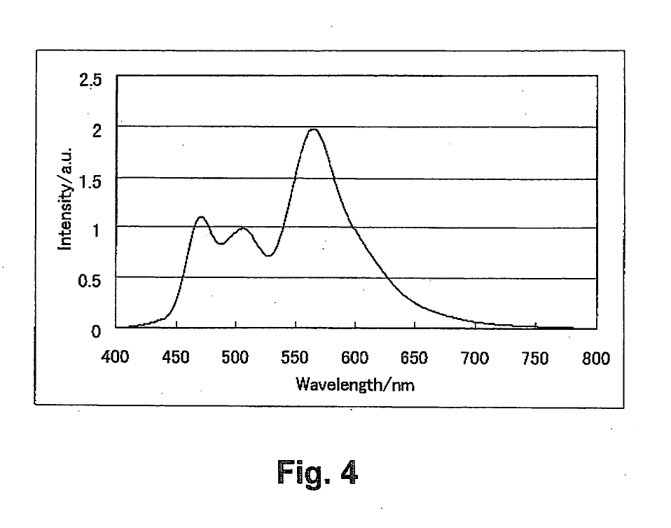

FIG. 4 shows the emission spectrum intensity of the EL element 500 (α=2.5) of Comparative Example 1-2 in which the NPB concentration in the first emissive layer EML1 was the lowest among the above three examples. As can be seen from FIG. 4, the emission luminance of the second emissive layer 340 was low while the first emissive layer 330 emitted light, making light emission by these two layers unbalanced, which resulted in emission of white light which was almost like yellow light. Further, the emission efficiency of the EL element 500 in Comparative Example was 10 cd/A (i.e. the power efficiency is 4.6 lm/W), which was lower than that of Example 1.

As can be understood from FIG. 4, in the EL element in Comparative Example 1-2, sufficient light emission could not be obtained in the second emissive layer. It is therefore possible to assume that if the concentration of the hole transporting material in the first emissive layer is low, a sufficient amount of holes cannot be transported into the second emissive layer 340 from the anode, which makes it difficult to cause a plurality of emissive layers to emit light in a balanced manner.

Further, in the EL elements 500 of Comparative Examples 2-1 and 2-2, the NPB concentrations of the HTL and the EML1 were 100% and 93.9, respectively, which were the sane as those in the Example 2 (and also Example 1). However, the NPB concentrations of the ELM2 in Comparative Examples 2-1 and 2-2 were 14.6% and 19.5%, respectively which were higher than that of 7.3% in Example 1. Further, while the light emission efficiency of the EL element in Example 1 was 14 cd/A as described above, those of the EL elements 500 in the Comparative Examples 2-1 and 2-2 were 11 cd/A and 7 cd/A (i.e. the power efficiency of 3.2 lm/W), respectively. As such, as the concentration of ADN which was an electron transporting compound in the second emissive layer (EML2) decreased (i.e. as the NPB concentration increased), the light emission efficiency was lowered.

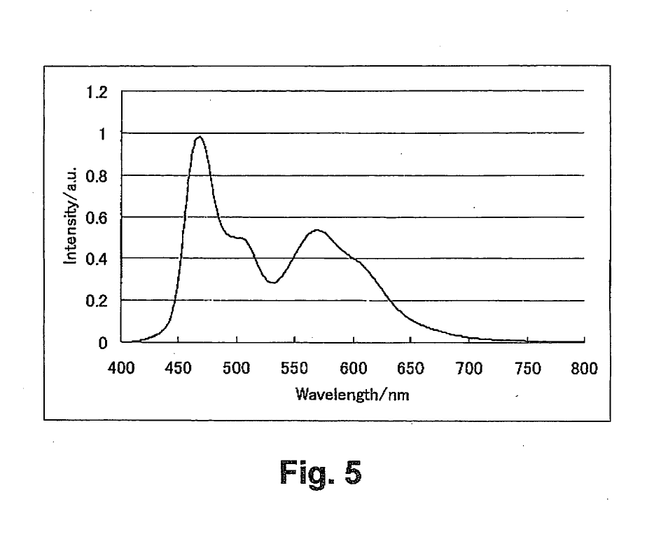

FIG. 5 shows the emission spectrum intensity of the EL element 500 (α=0.5) of Comparative Example 2-2. In contrast to Comparison Example 1-2 described above, the emission luminance of the first emissive layer 330 was low while the second emissive layer 340 emitted light, making light emission by these two layers unbalanced, which resulted in white light which was almost like blue light. Consequently, it can safely be assumed that, when the concentration of the electron transporting compound in the second emissive layer which also exhibits a function of transporting electrons from the electron transport layer to the first emissive layer is low, a sufficient amount of electrons cannot be transported into the first emissive layer 330, which prevents the first emissive layer from emitting sufficient light.

Here, in the above-described organic EL element in which the value of αis 1, the thickness of the hole injecting layer 310 was 10 nm and the mobility μhi was 10⁻³ cm²/Vs, the thickness of the hole transport layer 320 was 100 nm and the mobility μht was 10⁻³ cm²/Vs, the thickness of the first emissive layer 330 was 30.9 nm and the mobility μhem1 was 10⁻³ cm²/Vs, the thickness of the second emissive layer 340 was 41.0 nm and the mobility μhem2 was 10⁻³ cm²/Vs, and the thickness of the electron transport layer 350 was 10 nm and the mobility μht was 10⁻⁴ cm²/Vs. Of course, the combination of the film thickness and the mobility is not limited to those described above, and it is possible to cause a plurality of emissive layers to emit light efficiently and in a balanced manner, by fabricating the element such that the value of α is greater than approximately 1 and smaller than 2.5.

In addition, it can be understood from the above comparisons that, as the concentration of the hole transporting material in the second emissive layer (a blue emissive layer in this example) which is disposed further away from the anode than the first emissive layer increases, the light emission efficiency is lowered and the light emission balance is also deteriorated. Stated from a different viewpoint, as the concentration of the hole transporting material in the first emissive layer which is formed closer to the anode decreases, the ability to transport holes to the second emissive layer is lowered, causing a reduction in efficiency and deterioration in light emission balance.

Further, as the concentration of the electron transporting material in the first emissive layer (an orange emissive layer in this example) which is disposed further away from the cathode than the second emissive layer increases, the light emission efficiency is lowered and the light emission balance is also deteriorated. Stated from a different viewpoint, as the concentration of the electron transporting material in the second emissive layer which is formed closer to the cathode decreases, the ability to transport electrons to the second emissive layer is lowered, causing a reduction in efficiency and deterioration in light emission balance.

The following Table 2 shows a difference in concentrations of the hole transporting material in the first and second emissive layers and a difference in concentrations of the hole transporting material in the hole transport layer and the first emissive layer with regard to Example 1, and Comparative Examples 1-1 and 1-2.

TABLE 2

| | | | | Light |
|---|---|---|---|---|
| | | | | Emission |
| | | | (Cem1-Cem2)/ | Efficiency |
| | Cem1-Cem2 | Chi-Cem1 | (Chi-Cem1) | (cd/A) |
| Example 1(2) | 86.6 | 6.1 | 14.2 | 14 |
| Comparative | 80.1 | 12.6 | 6.4 | 12 |
| Example 1-1 | | | | |
| Comparative | 70.4 | 22.3 | 3.2 | 10 |
| Example 1-2 | | | | |

It is preferable that the concentration of the hole transporting material satisfies the relationship Cem1−Cem2>Chi−Cem1, as described above. Here, from the above-described results of Example 1, Comparative Example 1-1, and Comparative Example 1-2, it can be understood that it is more preferable that (Cem1−Cem2) is sufficiently greater than (Chi−Cem1) and is six times, more preferably approximately fourteen times (14.2 times in the element of Example 1), as great as (Chi−Cem1).

The organic EL element 500 according to the present embodiment can be used not only as a white display or flat light source which externally emits white light by an additive color, but also as a display which emits light of an arbitrary color by combining other colors.

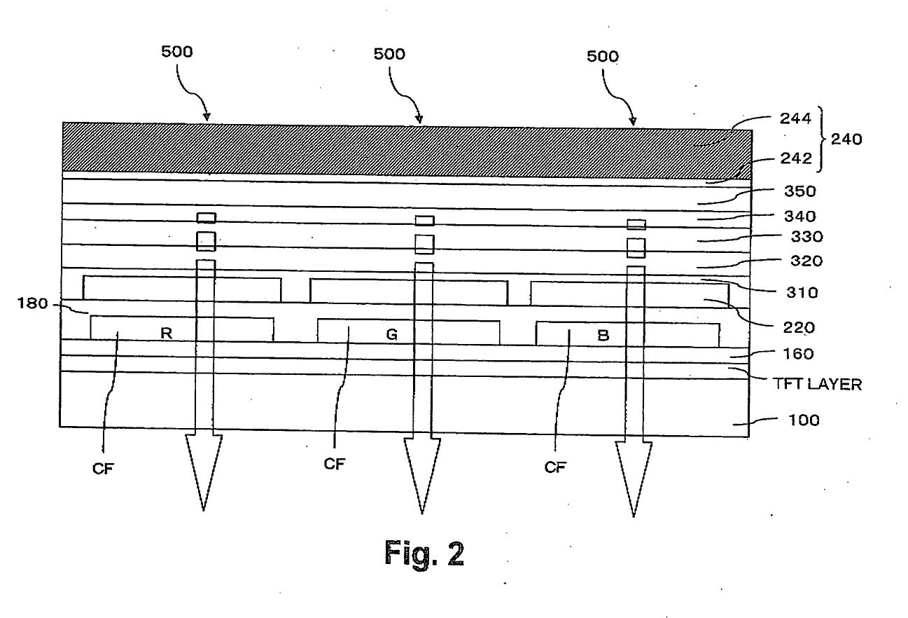

Further, as shown in FIG. 2, in a structure in which a corresponding one of color filters CF of three colors R, G, and B is formed between the white organic EL element 500 and the substrate, for example between an interlayer insulating layer 160 which insulates the transistor and a planarization insulating layer 180 for planarizing the element-forming surface, full color display can be achieved by causing only the desired R, G, or B light component to transmit through the white light component emitted from the organic EL element 500. Further, color display can be achieved by four colors of R, G, B and W (white) by not forming a color filter in some of pixels. The color filters are not limited to those of three colors of R, G, and B, and color filter of Y (yellow) and M (magenta) may further be provided.

While the preferred embodiment of the present invention has been described using specific terms, such description is for illustrative purposes only, and it is to be understood that changes and variations may be made without departing from the spirit or scope of the appended claims.

What is claimed is:

1. An electroluminescence element comprising, between a hole injecting electrode and an electron injecting electrode, an emissive element layer including a plurality of emissive layers, wherein
the emissive element layer includes two or more organic layers containing a hole transporting compound, one or more emissive layers of the plurality of emissive layers forming the organic layers containing a hole transporting compound, and
a concentration of the hole transporting compound contained in an organic layer of the organic layers which is formed closest to the electron injecting electrode is lower than a concentration of the hole transporting compound contained in an organic layer of the organic layers which is formed closest to the hole injecting electrode.

2. An electroluminescence element according to claim 1, wherein
the hole transporting compound is an amine derivative compound.

3. An electroluminescence element according to claim 1, wherein
the plurality of emissive layers include a first emissive layer which is disposed closest to the hole injecting electrode and a second emissive layer which is disposed between the first emissive layer and the electron injecting electrode,
at least a hole transport layer is provided between the first emissive layer and the hole injecting electrode, and
when a concentration of the hole transporting compound contained in the hole transport layer is represented by Ch1, a concentration of the hole transporting compound contained in the first emissive layer is represented by Cem1, and a concentration of the hole transporting compound contained in the second emissive layer is represented by Cem2, a relationship Cem1−Cem2>Ch1−Cem1 is satisfied.

4. An electroluminescence element according to claim 1, wherein
of the plurality of emissive layers, at least a first emissive layer which is disposed closest to the hole injecting electrode and an emissive layer which is formed closest to the first emissive layer contain the same hole transporting compound.

5. An electroluminescence element according to claim 1, wherein
of the plurality of emissive layers, a first emissive layer is disposed closest to the hole injecting electrode, and a second emissive layer is disposed between the first emissive layer and the electron injecting electrode,
at least a hole transport layer is provided between the first emissive layer and the hole injecting electrode,
at least an electron transport layer is provided between the second emissive layer and the electron injecting electrode, and
a concentration of an electron transporting compound contained in the electron transport layer, the second emissive layer, and the first emissive layer is set such that, as the layer is disposed further away from the electron transport layer, the concentration is lowered.

6. An electroluminescence element according to claim 1, wherein
at least a hole transport layer and a hole injecting layer are provided between the hole injecting electrode and a first emissive layer, of the plurality of emissive layers, which is disposed closest to the hole injecting electrodes
at least an electron transport layer is provided between the electron injecting electrode and a second emissive layer, of the plurality of emissive layers, which is disposed closest to the electron injecting electrode, and
when a thickness and a hole mobility of the hole injecting layer are represented by Lhi and μhi, respectively, a thickness and a hole mobility of the hole transport layer are represented by Lht and μht, respectively, a thickness and a hole mobility of the first emissive layer are represented by Lem1 and μhem1, respectively, a thickness and an electron mobility of the second emissive layer are represented by Lem2 and μhem2, respectively, and a thickness and an electron mobility of the electron transport layer are represented by Let and μet, respectively, the following relationship is satisfied:
(Lhi/μhi)+(Lht/μht)+(Lem1/μhem1)=α{(Lem2/μhem2)+(Let/μet)}
wherein α satisfies a relationship 0.5<α<2.5.

7. An electroluminescence element according to claim 1, wherein
three or more organic layers contain the hole transporting compound, and
a concentration of the hole transporting compound contained in the organic layers is set such that, as the layer is disposed further away from the hole injecting electrode, the concentration is lowered.

8. An electroluminescence element according to claim 7, wherein
the hole transporting compound is an amine derivative compound.

9. An electroluminescence element according to claim 7, wherein
the plurality of emissive layers include a first emissive layer which is disposed closest to the hole injecting electrode and a second emissive layer which is disposed between the first emissive layer and the electron injecting electrode,
at least a hole transport layer is provided between the first emissive layer and the hole injecting electrode, and
when a concentration of the hole transporting compound contained in the hole transport layer is represented by Ch1, a concentration of the hole transporting compound contained in the first emissive layer is represented by Cem1, and a concentration of the hole transporting compound contained in the second emissive layer is represented by Cem2, a relationship Cem1−Cem2>Ch1−Cem1 is satisfied.

10. An electroluminescence element according to claim 7, wherein
of the plurality of emissive layers, at least a first emissive layer which is disposed closest to the hole injecting electrode and an emissive layer which is formed closest to the first emissive layer contain the same hole transporting compound.

11. An electroluminescence element according to claim 7, wherein
of the plurality of emissive layers, a first emissive layer is disposed closest to the hole injecting electrode and a second emissive layer is disposed between the first emissive layer and the electron injecting electrode,
at least a hole transport layer is provided between the first emissive layer and the hole injecting electrode,
at least an electron transport layer is provided between the second emissive layer and the electron injecting electrode, and
a concentration of an electron transporting compound contained in the electron transport layer, the second emissive layer, and the first emissive layer is set such that, as the layer is disposed further away from the electron transport layer, the concentration is lowered.

12. An electroluminescence element according to claim 7, wherein
at least a hole transport layer and a hole injecting layer are provided between the hole injecting electrode and a first emissive layer, of the plurality of emissive layers, which is disposed closest to the hole injecting electrode,
at least an electron transport layer is provided between the electron injecting electrode and a second emissive layer, of the plurality of emissive layers, which is disposed closest to the electron injecting electrode, and
when a thickness and a hole mobility of the hole injecting layer are represented by Lhi and μhi, respectively, a thickness and a hole mobility of the hole transport layer are represented by Lht and μht, respectively, a thickness and a hole mobility of the first emissive layer are represented by Lem1 and μhem1, respectively, a thickness and an electron mobility of the second emissive layer are represented by Lem2 and μhem2, respectively, and a thickness and an electron mobility of the electron transport layer are represented by Let and μet, respectively, the following relationship is satisfied:
(Lhi/μhi)+(Lht/μht)+(Lem1/μhem1)=α{(Lem2/μhem2)+(Let/μet)}
wherein α satisfies the relationship 0.5<α<2.5.

13. An electroluminescence element comprising an emissive element layer including an organic compound between a hole injecting electrode and an electron injecting electrode, wherein
the emissive element layer includes a plurality of emissive layers, and at least a hole transport layer is provided between the hole injecting electrode and a first emissive layer, of the plurality of emissive layers, which is disposed closest to the hole injecting electrode, and at least an electron transport layer is provided between the electron injecting electrode and a second emissive layer, of the plurality of emissive layers, which is disposed closest to the electron injecting electrode, and
when an amount of time required for holes injected from the hole injecting electrode to pass through the hole transport layer and the first emissive layer to reach the second emissive layer is represented by Th and an amount of time required for electrons injected from the electron injecting electrode to pass through the electron transport layer and the second emissive layer to reach the first emissive layer is represented by Te, the ratio of Th/Te satisfies a relationship 0.5<(Th/Te)<2.5.

14. An electroluminescence element according to claim 13, wherein
the first emissive layer has a hole transporting function and the second emissive layer has an electron transporting function.

15. An electroluminescence element comprising an emissive element layer including an organic compound between a hole injecting electrode and an electron injecting electrode, wherein
the emissive element layer includes a plurality of emissive layers, and at least a hole transport layer is provided between the hole injecting electrode and a first emissive layer, of the plurality of emissive layers, which is disposed closest to the hole injecting electrode, and at least an electron transport layer is provided between the electron injecting electrode and a second emissive layer, of the plurality of emissive layers, which is disposed closest to the electron injecting electrode, and
when an amount of time required for holes injected from the hole injecting electrode to pass through the hole transport layer and the first emissive layer to reach the second emissive layer is represented by Th and an amount of time required for electrons injected from the electron injecting electrode to pass through the electron transport layer and the second emissive layer to reach the first emissive layer is represented by Te, the ratio of Th/Te satisfies a relationship 1≦(Th/Te)<2.

16. An electroluminescence element according to claim 15, wherein
the first emissive layer has a hole transporting function and the second emissive layer has an electron transporting function.

17. An electroluminescence element comprising an emissive element layer including an organic compound between a hole injecting electrode and an electron injecting electrode, wherein
the emissive element layer includes a plurality of emissive layers, and at least a hole transport layer and a hole injecting layer are provided between the hole injecting electrode and a first emissive layer, of the plurality of emissive layers, which is disposed closest to the hole injecting electrode, and at least an electron transport layer is provided between the electron injecting electrode and a second emissive layer, of the plurality of emissive layers, which is disposed closest to the electron injecting electrode, and
when a thickness and a hole mobility of the hole injecting layer are represented by Lhi and μhi, respectively, a thickness and a hole mobility of the hole transport layer are represented by Lht and μht, respectively, a thickness and a hole mobility of the first emissive layer are represented by Lem1 and μhem1, respectively, a thickness and an electron mobility of the second emissive layer are represented by Lem2 and μhem2, respectively, and a thickness and an electron mobility of the electron transport layer are represented by Let and μet, respectively, the following relationship is satisfied:
(Lhi/μhi)+(Lht/μht)+(Lem1/μhem1)=α{Lem2/μhem2)+(Let/μet)}
wherein α satisfies a relationship 0.5<α<2.5.

18. An electroluminescence element according to claim 17, wherein
the first emissive layer has a hole transporting function and the second emissive layer has an electron transporting function.
